(19) United States
(12) Patent Application Publication
(10) Pub. No.: US 2024/0298548 A1
(43) Pub. Date: Sep. 5, 2024

(54) MAGNETORESISTIVE ELEMENT, MAGNETIC SENSOR, AND MAGNETIC MEMORY

(71) Applicant: SONY SEMICONDUCTOR SOLUTIONS CORPORATION, KANAGAWA (JP)

(72) Inventors: YUTAKA HIGO, KANAGAWA (JP); LUI SAKAI, KANAGAWA (JP); MASAKI ENDO, KANAGAWA (JP); HIROYUKI OHMORI, KANAGAWA (JP); MASANORI HOSOMI, KANAGAWA (JP); TAKAYUKI NOZAKI, IBARAKI (JP); KAY YAKUSHIJI, IBARAKI (JP); MAKOTO KONOTO, IBARAKI (JP); TATSUYA YAMAMOTO, IBARAKI (JP); TOMOHIRO NOZAKI, IBARAKI (JP); SHINJI YUASA, IBARAKI (JP)

(21) Appl. No.: 18/573,045

(22) PCT Filed: Feb. 4, 2022
(86) PCT No.: PCT/JP2022/004362

§ 371 Date: Dec. 21, 2023

(30) Foreign Application Priority Data
Jun. 29, 2021 (JP) 2021-107765

(51) Int. Cl. H10N 50/10; G01R 33/09; H10N 50/80

(52) U.S. Cl. CPC H10N 50/10; G01R 33/098; H10N 50/80

(57) ABSTRACT

A magnetoresistive element according to the present embodiment includes a first magnetic layer (11) stacked on a base layer (10), a second magnetic layer (13), and a first nonmagnetic layer (12) arranged between the first magnetic layer (11) and the second magnetic layer (13). The first nonmagnetic layer (12) includes an insulating material including fluorine.

### FIELD

The present disclosure relates to a magnetoresistive element, a magnetic sensor, and a magnetic memory.

### BACKGROUND

Since having a large magnetoresistance effect at room temperature, a magnetic tunnel junction (MTJ) element is used as a storage element of a nonvolatile magnetic memory, or a high-sensitivity magnetic sensor. A basic structure of the MTJ element is a sandwich structure in which a nonmagnetic thin film (also referred to as a tunnel barrier layer) of an insulator is sandwiched between two magnetic layers including magnetic thin films. Since a film thickness of the nonmagnetic thin film is very thin and is about a several nm, when voltage is applied to both ends of the element, a tunnel current flows, and magnitude of the tunnel current depends on a relative angle of magnetization of the two magnetic layers. This is called a tunnel magneto resistance (TMR) effect.

In a case of the magnetic memory, magnetization of one magnetic layer is fixed (reference layer), magnetization of the other magnetic layer (recording layer) is controlled by an external field, and information (“0” or “1”) is stored in a nonvolatile manner by rewriting of parallel/antiparallel states of the magnetization. As the external field used for direction control of the magnetization, there is a current magnetic field generated by current energization to an external wiring line, a method of performing direct current energization with respect to the MTJ element and utilizing a spin angular momentum transfer effect, or a method utilizing magnetic anisotropy control by voltage. A TMR effect is used to read the information.

In realization of a large-capacity magnetic memory, a perpendicular magnetization-type MTJ element in which magnetization of a magnetic layer is oriented in a perpendicular direction is used. This is because, for example, in a case of a writing method using the spin angular momentum transfer effect, uniaxial magnetic anisotropy (perpendicular magnetic anisotropy) for stabilizing parallel and antiparallel magnetization can be designed to be large without a large increase in write energy. However, in constituent materials of the current MTJ element, there is a limitation on material options since it is necessary to achieve both the perpendicular magnetic anisotropy and the TMR effect, and it is considered difficult to secure perpendicular magnetic anisotropy suitable for an ultra-Gbit class large-capacity magnetic memory only with a cobalt iron (CoFe) alloy for a magnetic layer and a magnesium oxide (MgO) for a nonmagnetic layer that are used generally.

On the other hand, the magnetic sensor is a device that converts an external magnetic field into an electric signal and performs detection, and is widely used for a magnetic head in a magnetic recording medium, a rotation/angle sensor, a current sensor, a position sensor, a biomagnetic sensor, and the like in an in-vehicle electrical device or an industrial device, and the like. Specifically, a magnetic sensor using the MTJ element has a characteristic that high sensitivity can be acquired since a resistance change amount with respect to a change in a magnetic field is large. In the magnetic sensor, a relative angle change of the magnetization of the two magnetic layers due to magnitude of a magnetic field applied from the outside is electrically detected by the TMR effect.

In the magnetic sensor, the MTJ element in which a magnetization direction of one magnetic layer of the two magnetic layers is fixed (reference layer) and an easy axis of magnetization of the other magnetic layer (hereinafter, referred to as a magnetic field detection layer) is designed in a direction inclined by 90 degrees with respect to the magnetization of the reference layer is used. A magnetic field is detected by an element resistance change generated when the magnetization of the detection layer is inclined in response to the external magnetic field. For example, in a case where the magnetization of the reference layer is fixed in one in-plane direction and a perpendicular magnetization film is used for the magnetic field detection layer, intensity of an in-plane magnetic field in a direction parallel to the reference layer can be detected. In a case where the magnetization of the magnetic field detection layer is saturated in the in-plane direction, no further resistance change is generated. Thus, in order to enable detection in a wide magnetic field region, it is important to secure large perpendicular magnetic anisotropy in the magnetic field detection layer.

In order to acquire a magnetoresistive element having an excellent characteristic, it is important to improve a characteristic of a tunnel barrier layer (see, for example, Patent Literature 1). In Patent Literature 1, since an additive element selected from fluorine (F), sulfur (S), hydrogen (H), and lithium (Li) is further contained in a nonmagnetic layer (tunnel barrier layer) made of MgO, a defect and a crystal grain boundary present in the tunnel barrier layer are compensated with the additive element, and crystallinity is improved and electrical leakage is controlled.

### CITATION LIST

### Patent Literature

Patent Literature 1: Japanese Patent Application Laid-open No. 2020-155565

### SUMMARY

### Technical Problem

The present embodiment provides a magnetoresistive element, a magnetic sensor, and a magnetic memory having high perpendicular magnetic anisotropy and a high TMR ratio.

### Solution to Problem

A magnetoresistive element according to the present embodiment includes a first magnetic layer stacked on a base layer, a second magnetic layer, and a first nonmagnetic layer arranged between the first magnetic layer and the second magnetic layer. The first nonmagnetic layer includes an insulating material including fluorine.

### BRIEF DESCRIPTION OF DRAWINGS

FIG. 1 is a cross-sectional view of a magnetoresistive element of a first embodiment.

FIG. 2 is a cross-sectional view of a magnetoresistive element of a second embodiment.

FIG. 3 is a cross-sectional view of a magnetoresistive element of a third embodiment.

FIG. 4 is a cross-sectional view of a magnetoresistive element of a fourth embodiment.

FIG. 5 is a cross-sectional view of a magnetoresistive element of a fifth embodiment.

FIG. 6 is a cross-sectional view of a magnetoresistive element of a sixth embodiment.

FIG. 7 is a cross-sectional view of a magnetoresistive element of a seventh embodiment.

FIG. 8 is a cross-sectional view of a magnetoresistive element of an eighth embodiment.

FIG. 9 is a cross-sectional view of a magnetoresistive element of a ninth embodiment.

FIG. 10A is a schematic diagram of an element structure of a first example.

FIG. 10B is a view illustrating a magnetic characteristic comparison example by a magneto-optical effect of the first example.

FIG. 11A is schematic diagram of a structure of a magnetoresistive element of a second example.

FIG. 11B is a view illustrating a magnetic characteristic comparison example by magnetoresistance effect measurement of the second example.

FIG. 11C is a view illustrating an element resistance and MR effect characteristic comparison example by the magnetoresistance effect measurement of the second example.

FIG. 12A is a schematic diagram of an element structure of a third example.

FIG. 12B is a view illustrating a magnetic characteristic comparison example by a magneto-optical effect of the third example.

FIG. 13A is a schematic diagram of an element structure of a fourth example.

FIG. 13B is a view illustrating a magnetic characteristic comparison example by a magneto-optical effect of the fourth example.

FIG. 14A is view illustrating a configuration example of a magnetic sensor of a fifth example.

FIG. 14B is a schematic diagram of a magnetization response of a magnetic field detection layer of when a positive magnetic field and a negative magnetic field are applied.

FIG. 14C is a schematic diagram of the magnetization response of the magnetic field detection layer of when the positive magnetic field and the negative magnetic field are applied.

FIG. 14D is a view illustrating a change in element resistance with respect to a magnetic field.

FIG. 15A is a schematic partial cross-sectional view and an equivalent circuit diagram of a magnetic memory of a sixth example.

FIG. 15B is the schematic partial cross-sectional view and the equivalent circuit diagram of the magnetic memory of the sixth example.

FIG. 16 is a schematic perspective view of the magnetic memory of the sixth example.

### DESCRIPTION OF EMBODIMENTS

In the following, embodiments of the present disclosure will be described in detail on the basis of the drawings. Note that in the following embodiment, overlapped description is omitted by assignment of the same reference sign to the same parts. In addition, the present disclosure is not limited to the examples, and various numerical values and materials in the examples are examples.

A magnetoresistive element according to the present embodiment has a characteristic that an insulator including fluorine is introduced into a nonmagnetic layer serving as a tunnel barrier and a high TMR ratio is maintained while large perpendicular magnetic anisotropy is given.

A cross-sectional view of a magnetoresistive element according to a first embodiment is illustrated in FIG. 1. The magnetoresistive element according to the first embodiment has a stacked structure in which a base layer 10, a first magnetic layer 11, a first nonmagnetic layer 12, and a second magnetic layer 13 are stacked in this order. A fluoride insulator is used for the first nonmagnetic layer 12. Large perpendicular magnetic anisotropy is given at each of interfaces between the first magnetic layer 11 and the first nonmagnetic layer 12, and between the first nonmagnetic layer 12 and the second magnetic layer 13.

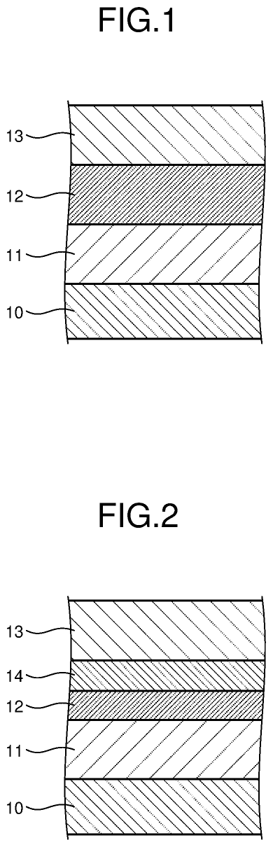

FIG. 2 is a cross-sectional view of a magnetoresistive element according to a second embodiment. The magnetoresistive element according to the second embodiment has a characteristic that a second nonmagnetic layer 14 is arranged on a first nonmagnetic layer 12 and a stacked-structured nonmagnetic layer is included in addition to the structure of the first embodiment. As a material of the second nonmagnetic layer 14, an oxide insulator and a nitride insulator can be used in addition to a fluoride insulator. Similarly to the first embodiment, the first nonmagnetic layer 12 gives large perpendicular magnetic anisotropy to the first magnetic layer 11. Purposes of material selection of the second nonmagnetic layer 14 are to adjust an element resistance value, enhance a TMR effect, and adjust relative permittivity of the nonmagnetic layer, for example. Note that stacking order of the first nonmagnetic layer 12 and the second nonmagnetic layer 14 may be reversed. In this case, large perpendicular magnetic anisotropy is given to an interface on a side of a second magnetic layer 13.

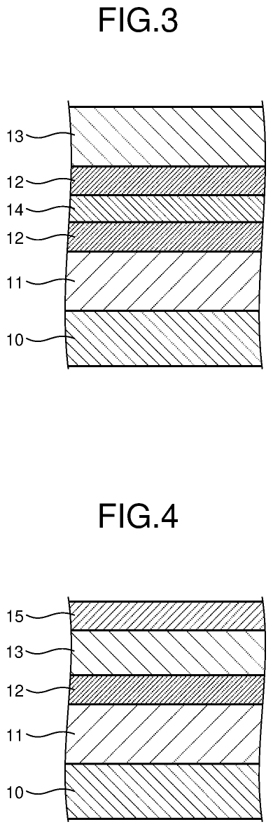

A cross-sectional view of a magnetoresistive element according to a third embodiment is illustrated in FIG. 3. The magnetoresistive element according to the third embodiment has a structure in which a first nonmagnetic layer 12 is inserted again between the second nonmagnetic layer 14 and the second magnetic layer 13 of the second embodiment, and the nonmagnetic layer has a three-layer stacked structure. Since both a first magnetic layer 11 and the second magnetic layer 13 are in contact with the first nonmagnetic layer 12 including a fluoride insulator, large perpendicular magnetic anisotropy can be given. Purposes of material selection of the second nonmagnetic layer 14 are similar to those of the second embodiment.

A cross-sectional view of a magnetoresistive element according to a fourth embodiment is illustrated in FIG. 4. The magnetoresistive element according to the fourth embodiment has a structure in which a third nonmagnetic layer 15 is arranged on the second magnetic layer 13 of the first embodiment. Any one of a fluoride insulator, an oxide insulator, or a nitride insulator can be used as a material of the third nonmagnetic layer 15. As a result, perpendicular magnetic anisotropy can be given to the second magnetic layer 13 also from a side of an interface between the second magnetic layer 13 and the third nonmagnetic layer 15. Thus, the perpendicular magnetic anisotropy of the second magnetic layer 13 can be further enhanced as compared with the first embodiment.

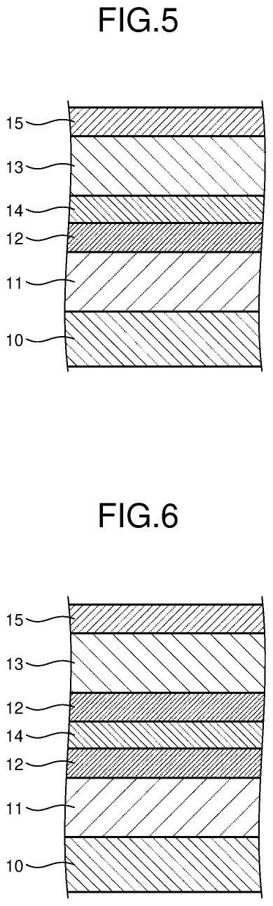

A cross-sectional view of a magnetoresistive element according to a fifth embodiment is illustrated in FIG. 5. The magnetoresistive element according to the fifth embodiment has a structure in which a third nonmagnetic layer 15 is arranged on the second magnetic layer 13 of the second embodiment. In the magnetoresistive element according to the fifth embodiment, in a case where perpendicular magnetic anisotropy of the second magnetic layer 13 is reduced by a second nonmagnetic layer 14 introduced for a reason similar to that in the second embodiment, perpendicular magnetic anisotropy can be given at an interface on a side of the second magnetic layer 13 and the third nonmagnetic layer 15. Note that stacking order of a first nonmagnetic layer 12 and the second nonmagnetic layer 14 may be reversed similarly to the second embodiment. In that case, perpendicular magnetic anisotropy on a side of the second magnetic layer 13 is enhanced by the first nonmagnetic layer 12.

A cross-sectional view of a magnetoresistive element according to a sixth embodiment is illustrated in FIG. 6. The magnetoresistive element according to the sixth embodiment has a structure in which a third nonmagnetic layer 15 is arranged on the second magnetic layer 13 of the third embodiment. Perpendicular magnetic anisotropy of the second magnetic layer 13 which perpendicular magnetic anisotropy is enhanced at an interface with a first nonmagnetic layer 12 arranged on an upper side among nonmagnetic layers having a three-layer stacked structure of the first nonmagnetic layer 12, a second nonmagnetic layer 14, and the first nonmagnetic layer 12 can be further enhanced by utilization of an interface with a side of the third nonmagnetic layer 15.

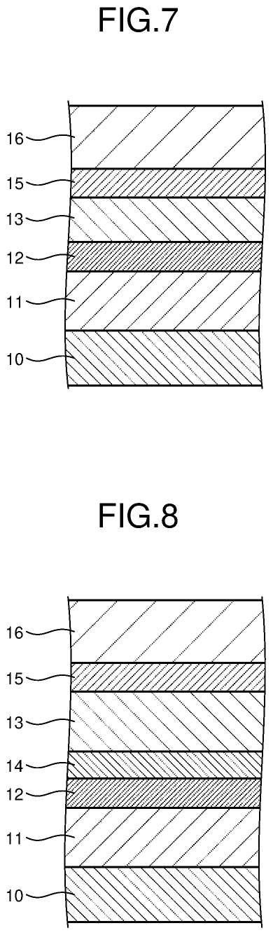

A cross-sectional view of a magnetoresistive element according to a seventh embodiment is illustrated in FIG. 7. The magnetoresistive element according to the seventh embodiment has a structure, in which a third magnetic layer 16 is arranged on the third nonmagnetic layer 15 of the fourth embodiment, and has a magnetoresistive element structure having two tunnel barrier layers of a first nonmagnetic layer 12 and the third nonmagnetic layer 15 with a second magnetic layer 13 interposed therebetween. In the magnetoresistive element according to the seventh embodiment, a TMR effect between a first magnetic layer 11 and the second magnetic layer 13 via the first nonmagnetic layer 12 and a TMR effect between the second magnetic layer 13 and the third magnetic layer 16 via the third nonmagnetic layer 15 can also be used at the same time. As a result, the magnetoresistive element according to the seventh embodiment can be designed in consideration of role sharing such as reduction of bias voltage dependency of the TMR effect, enhancement of perpendicular magnetic anisotropy to one nonmagnetic layer, and enhancement of the TMR effect to the other nonmagnetic layer.

A cross-sectional view of a magnetoresistive element according to an eighth embodiment is illustrated in FIG. 8. The magnetoresistive element according to the eighth embodiment has a structure in which a third magnetic layer 16 is arranged on the third nonmagnetic layer 15 of the fifth embodiment, and has a magnetoresistive element structure including two tunnel barrier layers similarly to the seventh embodiment. However, a lower nonmagnetic layer has a stacked structure of a first nonmagnetic layer 12 and a second nonmagnetic layer 14.

In the magnetoresistive element according to the eighth embodiment, in a case where perpendicular magnetic anisotropy of a second magnetic layer 13 is reduced by the second nonmagnetic layer 14 introduced for a reason similar to that in the second embodiment, the perpendicular magnetic anisotropy can be enhanced at an interface on a side of the second magnetic layer 13 and the third nonmagnetic layer 15. Furthermore, the magnetoresistive element according to the eighth embodiment can also utilize a TMR effect between the second magnetic layer 13 and the third magnetic layer 16 via the third nonmagnetic layer 15. Thus, the magnetoresistive element according to the eighth embodiment can be designed in consideration of role sharing such as reduction of bias voltage dependency of the TMR effect, enhancement of perpendicular magnetic anisotropy to one nonmagnetic layer, and enhancement of the TMR effect to the other nonmagnetic layer similarly to the seventh embodiment. Note that arrangements of the stacked structure of the first nonmagnetic layer 12/the second nonmagnetic layer 14 and the third nonmagnetic layer 15 may be reversed.

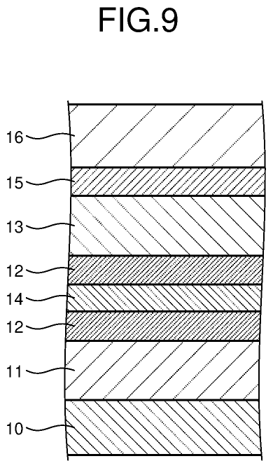

A cross-sectional view of a magnetoresistive element according to a ninth embodiment is illustrated in FIG. 9. The magnetoresistive element according to the ninth embodiment has a structure in which a third magnetic layer 16 is arranged on the third nonmagnetic layer 15 of the sixth embodiment, and has a magnetoresistive element structure having two tunnel barrier layers similarly to the seventh embodiment and the eighth embodiment. However, a lower nonmagnetic layer has a three-layer structure of a first nonmagnetic layer 12, a second nonmagnetic layer 14, and the first nonmagnetic layer 12. In the magnetoresistive element according to the ninth embodiment, perpendicular magnetic anisotropy of a second magnetic layer 13 which perpendicular magnetic anisotropy is increased at an interface with the first nonmagnetic layer 12 arranged on an upper side among the nonmagnetic layers having the three-layer stacked structure of the first nonmagnetic layer 12, the second nonmagnetic layer 14, and the first nonmagnetic layer 12 can be further enhanced by utilization of an interface with a side of the third nonmagnetic layer 15. Furthermore, in the magnetoresistive element according to the ninth embodiment, in addition to a TMR effect between a first magnetic layer 11 and the second magnetic layer 13 via the first nonmagnetic layer 12, the second nonmagnetic layer 14, and the first nonmagnetic layer 12, a TMR effect between the second magnetic layer 13 and the third magnetic layer 16 via the third nonmagnetic layer 15 can also be used. Thus, the magnetoresistive element according to the ninth embodiment can be designed in consideration of role sharing such as reduction of bias voltage dependency of the TMR effect, enhancement of perpendicular magnetic anisotropy to one nonmagnetic layer, and enhancement of the TMR effect to the other nonmagnetic layer similarly to the seventh embodiment and the eighth embodiment. Note that arrangements of the stacked structure of the first nonmagnetic layer 12/the second nonmagnetic layer 14/the first nonmagnetic layer 12 and the third nonmagnetic layer 15 may be reversed.

Note that in Patent Literature 1, since an additive element selected from fluorine (F), sulfur (S), hydrogen (H), and lithium (Li) is further contained in a nonmagnetic layer (tunnel barrier layer) made of MgO, a defect and a crystal grain boundary present in the tunnel barrier layer are compensated with the additive element, and crystallinity is improved and electrical leakage is controlled. Methods of containing a single or a plurality of additive elements in the tunnel barrier layer (MgO tunnel barrier layer) which methods are disclosed in Patent Literature 1 are as follows.

In a first method, an MgO layer to which an additive element is added is deposited by a sputtering method or a vapor deposition method by utilization of an MgO target to which the additive element is added. In a second method, a substrate is exposed to the oxygen atmosphere after an Mg layer to which an additive element is added is deposited or while the Mg layer to which the additive element is added is deposited by utilization of an Mg target to which the additive element is added. In a third method, a chip of an additive element is attached onto an MgO target, and an MgO layer to which the additive element is added is deposited by a sputtering method or a vapor deposition method.

In the MgO tunnel barrier layers that contain the additive elements and that are acquired by the above methods, the additive elements are randomly distributed in the MgO layers.

On the other hand, in the present disclosure, the fluoride insulator is a thin film layer included in a nonmagnetic layer, and has a form essentially different from that of Patent Literature 1 in which an element selected from fluorine (F), sulfur (S), hydrogen (H), and lithium (Li) is randomly added in a nonmagnetic layer. In addition, the large perpendicular magnetic anisotropy acquired by the present invention is induced by the presence of the interface between the magnetic layer and the nonmagnetic layer including the fluoride insulator. In the random addition as in Patent Literature 1, since there is no interface between the magnetic layer and the nonmagnetic layer including the fluoride insulator, large perpendicular magnetic anisotropy cannot be exhibited.

Next, materials of each of the members included in the magnetoresistive elements according to the first to ninth embodiments will be described.

### [First Magnetic Layer 11, Second Magnetic Layer 13, and Third Magnetic Layer 16]

For each of the first magnetic layer 11, the second magnetic layer 13, and the third magnetic layer 16, a layer made of a magnetic element such as Fe, Co, Ni, Mn, Nd, Sm, or Tb, or an alloy thereof can be used. In addition, it is also possible to use a magnetic layer made of a multilayer structure in which the above magnetic element is stacked, or a magnetic layer made of a multilayer structure in which the above magnetic element and at least one of Pt, Pd, Ir, Ru, Re, Rh, Os, Au, Ag, Cu, Re, W, Mo, Bi, V, Ta, Cr, Ti, Zn, Si, Al, or Mg are stacked. As the first magnetic layer 11, the second magnetic layer 13, and the third magnetic layer 16, a crystal layer lattice-matched with the first nonmagnetic layer 12, the second nonmagnetic layer 14, and the third nonmagnetic layer 15, specifically, a bcc (001) structure is generally used. However, it is also possible to perform forming as an amorphous layer at the time of film formation and to perform crystallization through a solid-phase epitaxy process by subsequent heat treatment.

### [First Nonmagnetic Layer 12]

An insulator including fluorine is used for the first nonmagnetic layer 12. Specifically, at least one kind of fluoride insulator selected from a group including LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, and TiO₂F is used. Specifically, it is more preferable to use LiF having good lattice matching with a FeCo alloy that has the bcc structure and that is a magnetic layer generally used for the MTJ element.

### [Second Nonmagnetic Layer 14 and Third Nonmagnetic Layer 15]

For the second nonmagnetic layer 14 and the third nonmagnetic layer 15, in addition to the same fluoride insulator as the first nonmagnetic layer 12, an oxide of at least one kind of element selected from a group of Mg, Al, Ti, Si, Zn, Zr, Hf, Ta, Bi, Cr, Ga, La, Gd, Sr, and Ba, or a nitride of at least one kind of element selected from a group of Mg, Al, Ti, Si, Zn, Zr, Hf, Ta, Bi, Cr, Ga, La, Gd, Sr, and Ba is used. Specifically, it is more preferable to use MgO, MgAl₂O₄, Al₂O₃, or the like having good lattice matching with LiF and having a high TMR ratio.

### [Base Layer 10]

As the base layer 10, for example, a layer made of a noble metal or a transition metal element such as Cr, Ta, Ru, Au, Ag, Cu, Al, Ti, V, Mo, Zr, Hf, Re, W, Pt, Pd, Ir, or Rh, and a stacked structure thereof can be used. Specifically, in a case where a CoFe alloy thin film having a bct structure is used for the first magnetic layer 11, it is effective to use Ir, Rh, Pd, and Pt, and an alloy including these elements as materials of the base layer 10. In addition, in a case where the first magnetic layer 11 is used as a magnetization fixed layer, the base layer 10 including an antiferromagnetic alloy such as IrMn or PrMn in the stacked structure can be used. Furthermore, the base layer 10 can also be used as a lower electrode layer.

The various layers described above can be produced by, for example, a physical vapor deposition (PVD) method represented by a sputtering method, an ion beam deposition method, and a vacuum deposition method, and a chemical vapor deposition (CVD) method represented by an atomic layer deposition (ALD) method. Patterning of these layers can be performed by a reactive ion etching (RIE) method or an ion milling method. The various layers are preferably formed continuously in a vacuum device, and the patterning is preferably performed thereafter.

Hereinafter, examples based on experimental results will be described.

### First Example

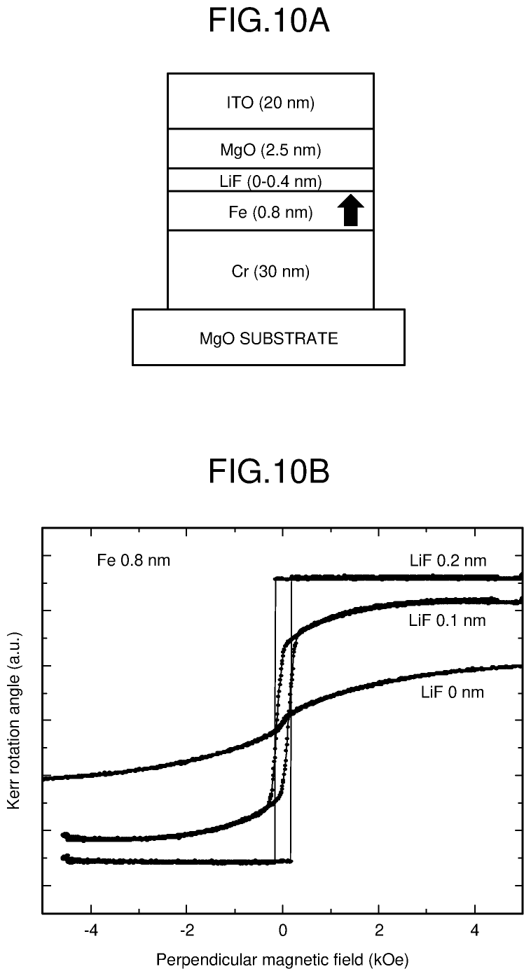

As the first example, as illustrated in FIG. 10A, a multilayer film structure in which Cr (30 nm) was used for the base layer 10, Fe (0.8 nm) was used for the first magnetic layer 11, LiF (0-0.4 nm) was used for the first nonmagnetic layer 12, MgO (2.4 nm) was used for the second nonmagnetic layer 14, and indium tin oxide (20 nm) (hereinafter referred to as ITO) that was transparent conductive oxide was used for an upper electrode was produced on an MgO (001) substrate. In a case of the magnetoresistive element, the second magnetic layer 13 is arranged instead of the ITO layer. However, in the present example, a nonmagnetic ITO electrode is used to evaluate an influence of insertion of an LiF layer on a magnetic characteristic of an Fe layer. Each of Cr, Fe, LiF, and MgO is a (001) single crystal film. In order to compare film thickness dependency of LiF, multilayer film structures in which a film thickness of LiF is changed in a range of 0 nm to 0.4 nm are produced on the same substrate. Films other than the ITO film were formed by a molecular beam epitaxy method, and the ITO film was formed by sputtering. The Cr layer was formed at 200° C., and then heat-treated at 800° C. for 10 minutes. The Fe layer was formed at 150° C., and then heat-treated at 250° C. for 10 minutes. The nonmagnetic layer stacked layers of LiF and MgO were formed at room temperature, and then heat-treated at 350° C. for 10 minutes. An ITO upper electrode was formed at the room temperature.

FIG. 10B is a view illustrating LiF film thickness dependency of a magnetic characteristic of the Fe layer, which dependency is evaluated by a magneto-optical effect, under application of a magnetic field in a direction perpendicular to a film surface. A horizontal axis illustrated in FIG. 10B represents magnitude of the magnetic field applied from the outside in the direction perpendicular to the film surface. A unit of intensity on the horizontal axis is kOe. 1 Oe corresponds to (¼ π)*10³ A/m. A vertical axis represents a Kerr rotation angle (arbitrary unit) that is a polarization angle of reflected light received by laser emission from above. In a case where LiF is not inserted, magnetization is not saturated in the perpendicular direction even when a magnetic field of 4 kOe or more is applied, and an in-plane magnetization film is acquired. On the other hand, in a case where LiF is inserted for 0.1 nm, the magnetization is saturated in the perpendicular direction by a magnetic field of about 2 kOe. In a case where LiF is inserted for 0.2 nm, the Fe layer is a perpendicular magnetization film having the perpendicular direction as an easy axis of magnetization. From these comparisons, it can be seen that the perpendicular magnetic anisotropy of the first magnetic layer 11 can be enhanced by utilization of a fluoride insulator for the first nonmagnetic layer 12. A thickness of the inserted first nonmagnetic layer 12 is preferably 0.1 nm or more, and is more preferably 0.2 nm or more.

### Second Example

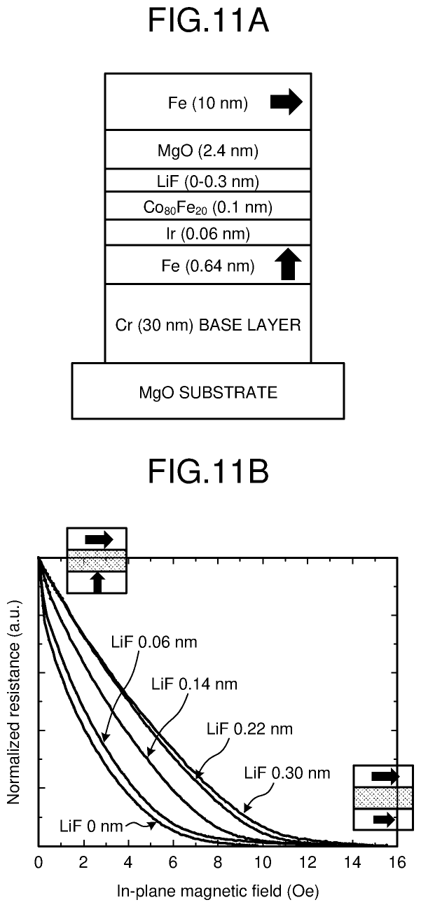

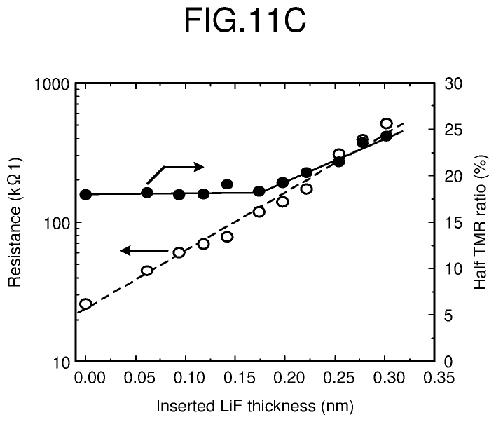

As the second example, as illustrated in FIG. 11A, a magnetoresistive element in which Cr (30 nm) was used for the base layer 10, a stacked structure magnetic layer made of Fe (0.64 nm)/Ir (0.06 nm)/Co₈₀Fe₂₀ (0.1 nm) was used for the first magnetic layer 11, LiF (0-0.4 nm) was used for the first nonmagnetic layer 12, MgO (2.4 nm) was used for the second nonmagnetic layer 14, and Fe (10 nm) was used for the second magnetic layer 13 was produced on an MgO (001) substrate. In order to compare film thickness dependency of LiF of the first nonmagnetic layer 12, a film thickness of LiF was changed in a range of 0 nm to 0.4 nm. These films were formed by the molecular beam epitaxy method. The Cr layer was formed at 200° C., and then heat-treated at 800° C. for 10 minutes. An Fe/Ir/Co₈₀Fe₂₀ stacked structure was formed at 150° C., and then heat-treated at 250° C. for 10 minutes. Since these stacked structures respond to a magnetic field as an integrated magnetic thin film, the stacked structures are collectively regarded as the first magnetic layer 11. The nonmagnetic layer stacked layers of LiF and MgO were formed at room temperature, and then heat-treated at 330° C. for 10 minutes. An upper Fe electrode was formed at 200° C., and then heat-treated at 250° C. for 10 minutes. Each of Cr, Fe/Ir/Co₈₀Fe₂₀ stacked layer, LiF, MgO, and the upper Fe layer is a (001) single crystal film.

FIG. 11B is a view illustrating LiF insertion thickness dependency of a normalized TMR curve under application of an in-plane magnetic field. Usually, in a magnetoresistive element for a magnetic memory, a perpendicular magnetization film is used for both the first magnetic layer 11 and the second magnetic layer 13. However, in the present experiment, in order to evaluate LiF layer insertion layer thickness dependency on the perpendicular magnetic anisotropy of the Fe layer, a lower Fe layer of the first magnetic layer 11 was a perpendicular magnetization film, and an upper Fe layer of the second magnetic layer 13 was an in-plane magnetization film as illustrated in the schematic diagram of FIG. 11A. In this case, when the in-plane magnetic field is applied, resistance becomes the lowest when the magnetization of the upper Fe layer remains parallel in the in-plane direction, only the magnetization of the lower Fe/Ir/Co₈₀Fe₂₀ stacked layer changes in the magnetization direction from the perpendicular direction to the in-plane direction, and both the Fe layers become parallel. Since magnetic field intensity necessary to create this parallel magnetization state (this is called an anisotropy field) reflects magnitude of perpendicular magnetic anisotropy of the lower Fe layer, the influence of LiF insertion on the perpendicular magnetic anisotropy can be evaluated by comparison of the magnitude of the anisotropy field. A unit of intensity on a horizontal axis is kOe. 1 Oe corresponds to (¼π)*10³ A/m. A vertical axis represents a resistance value (arbitrary unit) normalized with resistance at a zero magnetic field as 1 and resistance at an in-plane applied magnetic field of 16 kOe as 0. From the result of FIG. 11B, it can be seen that an anisotropy field of the lower Fe/Ir/Co₈₀Fe₂₀ stacked layer is increased to about 8 kOe in a case where LiF is inserted for 0.14 nm, and is increased to about 10 kOe in a case where LiF is inserted for 0.22 nm while the anisotropic magnetic field is about 6 kOe in a case where LiF is not inserted or in a case where LiF is inserted for 0.06 nm, and that the perpendicular magnetic anisotropy is increased. Note that a case where LiF is further thickened to 0.3 nm is substantially equivalent to the case of 0.22 nm, and it is understood that the above-described effect of increasing the perpendicular magnetic anisotropy can be sufficiently acquired when a surface of the lower Fe/Ir/Co₈₀Fe₂₀ stacked layer is covered for a half LiF unit (lattice constant of LiF is about 0.4 nm) or more. Also according to the present example, the thickness of the inserted first nonmagnetic layer 12 is preferably 0.1 nm or more, and is more preferably 0.2 nm or more.

FIG. 11C is a view illustrating the LiF insertion layer thickness dependency of the element resistance and the TMR ratio. A horizontal axis represents an LiF insertion layer thickness, a vertical left axis represents the element resistance (white circle in the graph), and a vertical right axis represents the TMR ratio (black circle in the graph), and the units thereof are respectively nm, kΩ, and %. Here, in the magnetoresistive element used in the present example, magnetization of a magnetic layer is arranged at 90 degrees in a zero magnetic field, and the TMR ratio is between the parallel magnetization state and the 90 degree magnetization state. Since this is approximately a half the TMR ratio of a case where a normal parallel-antiparallel resistance change is used, the right vertical axis represents a Half TMR ratio. The element resistance increases exponentially with respect to the LiF insertion, and it can be seen that an LiF film functions as a tunnel barrier layer. In addition, the TMR ratio shows a substantially constant value up to the LiF thickness of about 0.2 nm, and increases in a film thickness region of about 0.2 nm or more. This indicates that a TMR effect by a coherent tunneling mechanism similar to that of MgO is acquired in the LiF film of the half unit or more, and indicates that LiF insertion is an effective method for acquiring the large TMR effect. That is, a film thickness of the inserted first nonmagnetic layer 12 is preferably 0.2 nm or more from a viewpoint of a magnetoresistance effect characteristic.

### Third Example

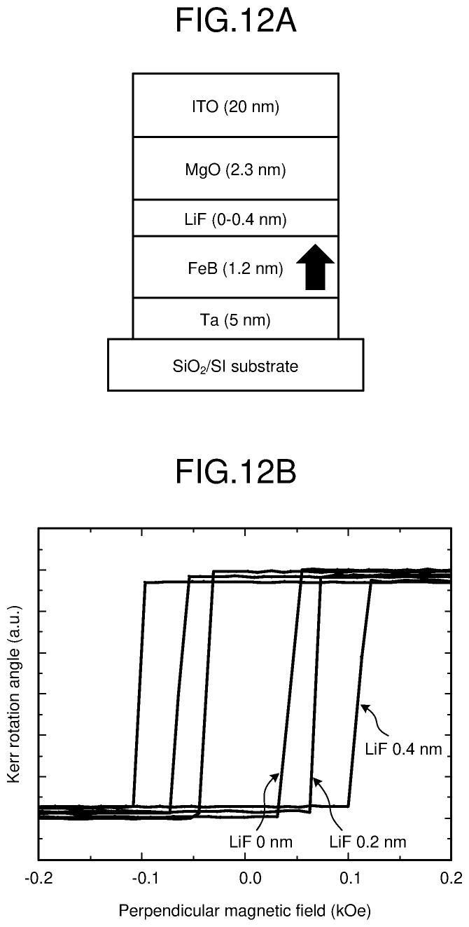

As the third example, as illustrated in FIG. 12A, a multilayer film structure in which Ta (5 nm) was used as the base layer 10, Fe₈₀B₂₀ (1.2 nm) was used as the first magnetic layer 11, LiF (0-0.4 nm) was used for the first nonmagnetic layer 12, MgO (2.3 nm) was used for the second nonmagnetic layer 14, and ITO (20 nm) was used for the upper electrode was produced on an Si substrate with a thermal oxide film. Similarly to the first example, in order to evaluate an LiF insertion effect on the Fe₈₀B₂₀ layer, an ITO thin film is used for the upper electrode. In order to compare film thickness dependency of LiF, multilayer film structures in which a film thickness of LiF is changed in a range of 0 nm to 0.4 nm are produced on the same substrate. Ta, Fe₈₀B₂₀, and ITO layers are formed by sputtering, and LiF and MgO layers are formed by molecular beam epitaxy. After a multilayer structure of Ta to MgO was formed at room temperature, heat treatment was performed at 250° C. for 10 minutes. The ITO upper electrode was formed at the room temperature. The Fe₈₀B₂₀ layer has an amorphous structure at the time of film formation, and partially has a bcc structure by solid-phase epitaxy after the heat treatment.

FIG. 12B is a view illustrating LiF film thickness dependency of a magnetic characteristic of the Fe₈₀B₂₀ layer, which dependency is evaluated by the magneto-optical effect, under application of a magnetic field in a direction perpendicular to a film surface. A unit of intensity on a horizontal axis is kOe. 1 Oe corresponds to (¼ π)*10³ A/m. A vertical axis represents a Kerr rotation angle (arbitrary unit). A perpendicular magnetization film is acquired in all of structures without LiF, with 0.2 nm LiF insertion, and with 0.4 nm LiF insertion. It can be seen that coercive force increases and the perpendicular magnetic anisotropy increases as the film thickness of inserted LiF increases. Note that saturated Kerr rotation angle intensity of the Fe₈₀B₂₀ layer hardly changes, and there is no influence such as a decrease in saturation magnetization due to the LiF insertion. Also according to the present example, the film thickness of the inserted first nonmagnetic layer 12 is preferably 0.2 nm or more.

### Fourth Example

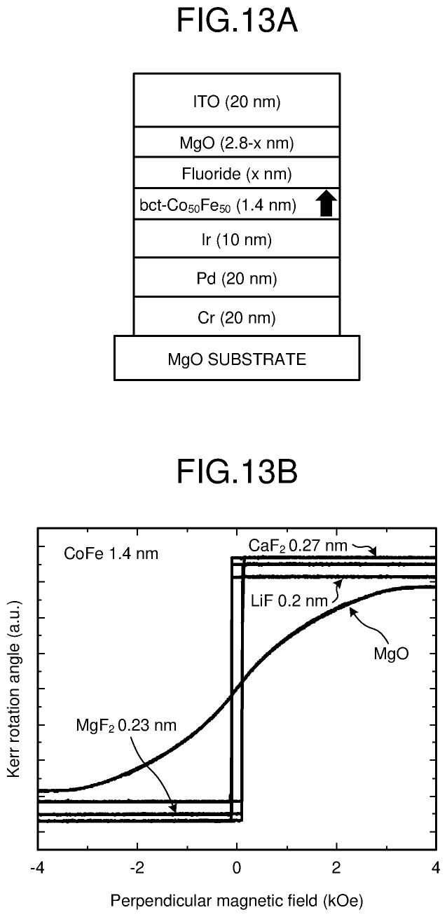

As the fourth example, as illustrated in FIG. 13A, a stacked structure in which Cr (20 nm)/Pd (20 nm)/Ir (10 nm) was used for the base layer 10, Co₅₀Fe₅₀ (1.4 nm) was used for the first magnetic layer 11, a fluoride insulator (X nm) was used for the first nonmagnetic layer 12, MgO ((2.8−X) nm) was used for the second nonmagnetic layer 14, and ITO (20 nm) was used for the upper electrode was produced on an MgO (001) substrate. The Co₅₀Fe₅₀ layer has a tetragonal (bct) structure due to an influence of lattice strain from a side of the Ir base layer. As fluoride insulators (denoted as Fluoride in the drawing), insertion of three kinds that are LiF, MgF₂, and CaF₂ was attempted. As an insertion layer thickness of each of the fluoride insulators, a film thickness corresponding to a half unit thickness of each material was inserted. Specifically, LiF was inserted for 0.2 nm, MgF₂ was inserted for 0.23 nm, and CaF₂ was inserted for 0.27 nm. The MgO film thereon was designed in such a manner that the total film thickness of the nonmagnetic layer 12/nonmagnetic layer 14 stacked structure was 2.8 nm. That is, MgO (2.6 nm) was used for LiF, MgO (0.257 nm) was used for MgF₂, and MgO (0.253 nm) was used for CaF₂. Films other than the ITO film were formed by a molecular beam epitaxy method, and the ITO film was formed by sputtering.

FIG. 13B is a view illustrating inserted fluoride material dependency of a magnetic characteristic of a bct-Co₅₀Fe₅₀ layer, which dependency is evaluated by the magneto-optical effect, under application of a magnetic field in a direction perpendicular to a film surface. A unit of intensity on a horizontal axis is kOe. 1 Oe corresponds to (¼π)*10³ A/m. A vertical axis represents a Kerr rotation angle (arbitrary unit). The bct-Co₅₀Fe₅₀ layer in a case where a fluoride insulating film is not inserted, that is, in a case of direct contact with MgO is an in-plane magnetization film, and it is necessary to apply a magnetic field of about 4 kOe for magnetization in the perpendicular direction. On the other hand, even in a case where a half unit of a fluoride insulator of any of LiF, MgF₂, or CaF₂ is inserted, a perpendicular magnetization film having an easy axis of magnetization in the perpendicular direction is acquired. From the above, it can be seen that an effect of increasing the perpendicular magnetic anisotropy can be acquired not only in LiF but also in various fluoride insulators. At this time, the film thickness of the inserted first nonmagnetic layer 12 is preferably about 0.2 nm or more corresponding to the half unit.

In the following, examples of a magnetic device including the magnetoresistive element described in in the first to fourth examples will be described.

### Fifth Example

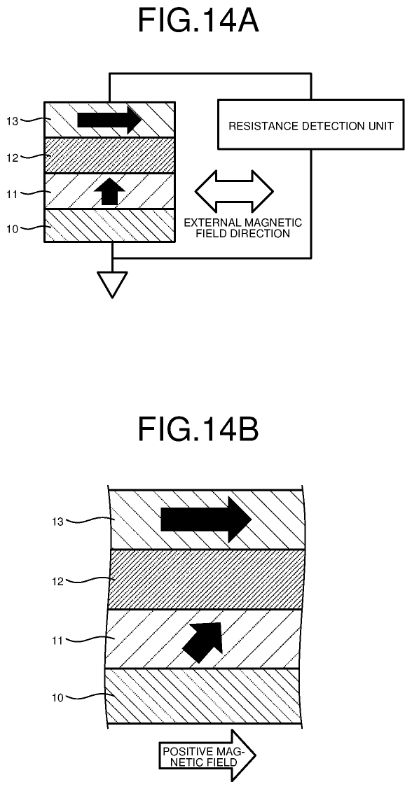

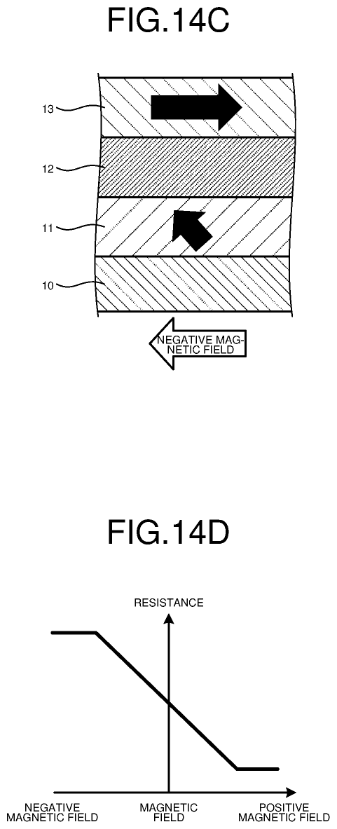

The fifth example relates to a magnetic device including the magnetoresistive element described in the first to fourth examples, specifically, a magnetic sensor. FIG. 14A is a view illustrating a configuration example of the magnetic sensor according to the present disclosure. It is assumed that the first magnetic layer 11 is the magnetic field detection layer, and the second magnetic layer 13 is the reference layer in which a magnetization direction is fixed in one in-plane direction. When a magnetization direction of the first magnetic layer 11 changes due to the external magnetic field, the element resistance changes. This change is detected by a resistance detection unit. For example, in a case where the magnetic field is applied in a right direction (defined as a positive magnetic field) as illustrated in FIG. 14B, a relative angle of magnetization becomes closer to a parallel state. Thus, the element resistance decreases. On the other hand, in a case where the magnetic field is applied in a left direction (defined as a negative magnetic field) as illustrated in FIG. 14C, the relative angle of magnetization becomes closer to an antiparallel state. Thus, the element resistance increases. The element resistance change with respect to the magnetic field is in a manner illustrated in FIG. 14D. The resistance changes linearly up to a region in which the anisotropy field of the first magnetic layer 11 is reached, and the magnetic field can be detected in this region. That is, as the anisotropy field becomes larger, the larger detectable magnetic field range can be secured. In the present disclosure, it is possible to provide the magnetic sensor that can give the large perpendicular magnetic anisotropy to the first magnetic layer 11 by using the first nonmagnetic layer 12, and that can detect the magnetic field in the wide region.

### Sixth Example

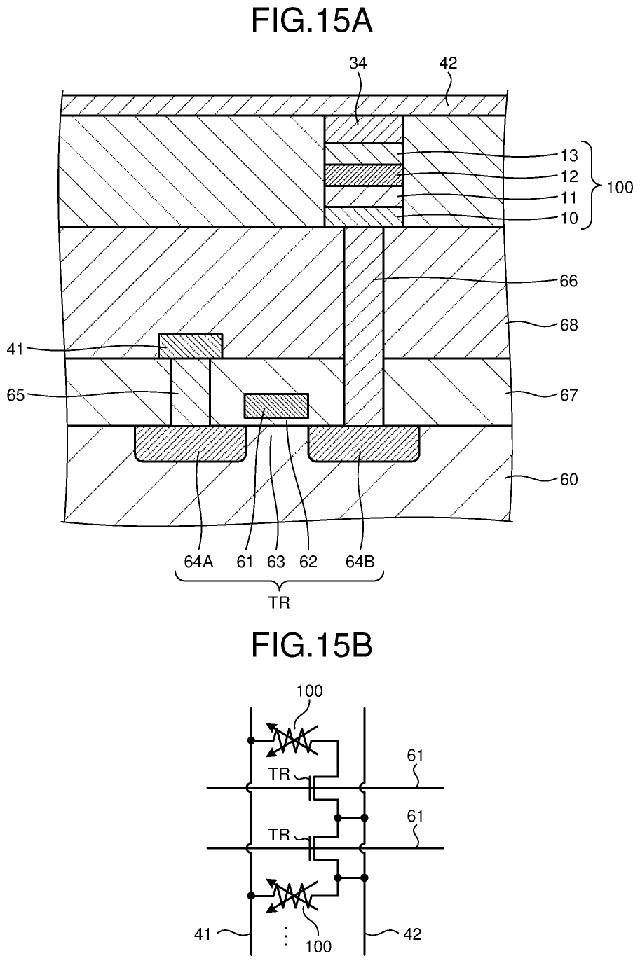

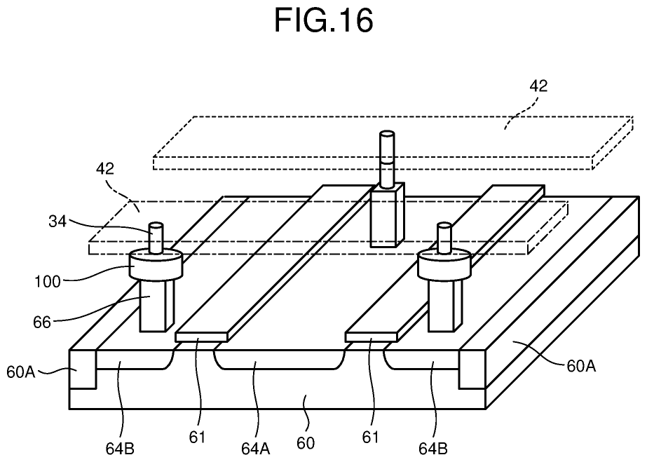

The sixth example relates to a magnetic device including the magnetoresistive element described in the first to fourth examples, specifically, a magnetic memory. A schematic partial cross-sectional view of the magnetic memory according to the present disclosure is illustrated in FIG. 15A, an equivalent circuit diagram thereof is illustrated in FIG. 15B, and a schematic perspective view thereof is illustrated in FIG. 16. A magnetoresistive element 100 of the present example has a stacked structure in which a base layer 10, a first magnetic layer 11, a first nonmagnetic layer 12, and a second magnetic layer 13 are stacked in this order. A selection transistor TR including a field effect transistor is provided below the magnetoresistive element 100.

Specifically, the selection transistor TR formed on a silicon semiconductor substrate 60, and a first interlayer insulating layer 67 that covers the selection transistor TR are included, and a first wiring line 41 is formed on the first interlayer insulating layer 67. The first wiring line 41 is electrically connected to one source/drain region 64A of the selection transistor TR via a connection hole (or a connection hole, a landing pad portion, or a lower layer wiring line) 65 provided in the first interlayer insulating layer 67.

A second interlayer insulating layer 68 covers the first interlayer insulating layer 67 and the first wiring line 41, and an insulating material layer 51 surrounding the magnetoresistive element 100 and a cap layer 34 is formed on the second interlayer insulating layer 68. A lower portion of the magnetoresistive element 100 is electrically connected to the other source/drain region 64B of the selection transistor TR via a connection hole 66 provided in the first interlayer insulating layer 67 and the second interlayer insulating layer 68.

A second wiring line 42 is formed on the insulating material layer 51, and an upper portion of the magnetoresistive element 100 is electrically connected to the second wiring line 42 via the cap layer 34. The selection transistor TR includes a gate electrode 61, a gate oxide film 62, a channel formation region 63, and the source/drain regions 64A and 64B. As described above, via the connection hole 65, the one source/drain region 64A and the first wiring line 41 are connected to the first wiring line (sense line) 41 formed on the first interlayer insulating layer 67.

In addition, the other source/drain region 64B is connected to the magnetoresistive element 100 via the connection hole 66. The gate electrode 61 also functions as a so-called word line or address line. A projection image in a direction in which the second wiring line (bit line) 42 extends is orthogonal to a projection image in a direction in which the gate electrode 61 extends, and is parallel to a projection image in a direction in which the first wiring line 41 extends. However, in FIG. 15A, in order to simplify the drawing, the extending directions of the gate electrode 61, the first wiring line 41, and the second wiring line 42 are different from the above.

In the following, an outline of a manufacturing method of the magnetic memory of the sixth example will be described. First, an element isolation region is formed in the silicon semiconductor substrate 60 on the basis of a known method, and the selection transistor TR including the gate oxide film 62, the gate electrode 61, and the source/drain regions 64A and 64B is formed in a portion of the silicon semiconductor substrate 60 which portion is surrounded by the element isolation region. A portion of the silicon semiconductor substrate 60 located between the source/drain region 64A and the source/drain region 64B corresponds to the channel formation region 63.

Then, the first interlayer insulating layer 67 is formed, the connection hole 65 is formed in a portion of the first interlayer insulating layer 67 which portion is above the one source/drain region 64A, and the first wiring line 41 is further formed on the first interlayer insulating layer 67. Subsequently, the second interlayer insulating layer 68 is formed on the entire surface, and the connection hole 66 is formed in a portion of the first interlayer insulating layer 67 and the second interlayer insulating layer 68 which portion is above the other source/drain region 64B. Thus, the selection transistor TR covered with the first interlayer insulating layer 67 and second interlayer insulating layer 68 can be acquired.

Then, the base layer 10, the first magnetic layer 11, the first nonmagnetic layer 12, the second magnetic layer 13, and the cap layer 34 are continuously formed on the entire surface. Then, the cap layer 34, the second magnetic layer 13, the first nonmagnetic layer 12, the first magnetic layer 11, and the base layer 10 are etched by utilization of, for example, an ion beam etching method (IBE method). The base layer 10 is in contact with the connection hole 66.

Then, the insulating material layer 51 is formed on the entire surface, and planarization processing is performed on the insulating material layer 51, whereby a top surface of the insulating material layer 51 is made to be at the same level as a top surface of the cap layer 34. Then, the second wiring line 42 in contact with the cap layer 34 is formed on the insulating material layer 51. From the above, the magnetic memory having the structure illustrated in FIG. 15A can be acquired. As described above, a general MOS manufacturing process can be applied to manufacturing of the magnetic memory of the sixth example, and the magnetic memory can be applied as a general-purpose memory.

As described above, since the magnetoresistive element, the magnetic memory, and the magnetic sensor according to the present disclosure have high perpendicular magnetic anisotropy as compared with a conventional structure, it is possible to secure high thermal stability at room temperature, and it is possible to provide a magnetic device having a small number of operation errors and a high operation margin. Note that the effects described in the present specification are merely examples and are not limitations, and there may be an additional effect.

Although the present invention has been described on the basis of preferred examples, the present invention is not limited to these examples, and can be implemented in various other forms. It is possible to make various omissions, substitutions, and changes without departing from the gist of the invention. In addition, various stacked structures, materials used, and the like described in the examples are examples, and can be appropriately changed.

Note that the present technology can also have the following configurations.

(1)

A magnetoresistive element including:
a first magnetic layer stacked on a base layer; a second magnetic layer; and a first nonmagnetic layer arranged between the first magnetic layer and the second magnetic layer, wherein
the first nonmagnetic layer includes
an insulating material including fluorine.
   (2)

The magnetoresistive element according to (1), wherein
the first nonmagnetic layer includes
the insulating material including fluorine, oxygen, or nitrogen.
   (3) The magnetoresistive element according to (1) or (2), further including
a second nonmagnetic layer between the first nonmagnetic layer and the second magnetic layer, wherein
the second nonmagnetic layer includes
a nonmagnetic layer having a stacked structure in which a fluoride insulator, an oxide insulator, or a nitride insulator is used.
   (4)

The magnetoresistive element according to any one of (1) to (3), wherein
a perpendicular magnetization film is used for both the first magnetic layer and the second magnetic layer, or any one of the first magnetic layer or the second magnetic layer.
   (5)

The magnetoresistive element according to any one of (1) to (3), wherein
the first nonmagnetic layer includes
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, or TiO₂F.
   (6)

The magnetoresistive element according to (3), wherein
the first nonmagnetic layer and the second nonmagnetic layer include
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, or TiO₂F, an oxide including at least any one of Mg, Al, Ti, Si, Zn, Zr, Hf, Ta, Bi, Cr, Ga, La, Gd, Sr, or Ba, or a nitride including at least any one of Mg, Al, Ti, Si, Zn, Zr, Hf, Ta, Bi, Cr, Ga, La, Gd, Sr, or Ba.
   (7)

The magnetoresistive element according to any one of (1) to (3), wherein
the first nonmagnetic layer includes
LiF.
   (8)

The magnetoresistive element according to (3), wherein
as a stacked structure of the first nonmagnetic layer and the second nonmagnetic layer,
a stacked structure of fluoride and MgO is used.
   (9)

The magnetoresistive element according to any one of (1) to (3), further including
a third nonmagnetic layer on the second magnetic layer, wherein
the third nonmagnetic layer includes
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, or TiO₂F, an oxide including at least any one of Mg, Al, Ti, Si, Zn, Zr, Hf, Ta, Bi, Cr, Ga, La, Gd, Sr, or Ba, or a nitride including at least any one of Mg, Al, Ti, Si, Zn, Zr, Hf, Ta, Bi, Cr, Ga, La, Gd, Sr, or Ba.
   (10)

The magnetoresistive element according to (9), further including
a third magnetic layer on the third nonmagnetic layer.
   (11)

The magnetoresistive element according to (10), wherein
as the first magnetic layer, the second magnetic layer, and the third magnetic layer,
a magnetic thin film having a bcc (001) crystal structure is used.
   (12)

The magnetoresistive element according to (10), wherein
as the first magnetic layer, the second magnetic layer, and the third magnetic layer,
a magnetic thin film having an amorphous structure is used.
   (13)

The magnetoresistive element according to any one of (1) to (3), (9), and (10), wherein
as the first magnetic layer,
a magnetic thin film having a bct (001) crystal structure is used.
   (14)

The magnetoresistive element according to (13), wherein
as the base layer,
Ir is used.
   (15)

A magnetic sensor including: the magnetoresistive element according to any one of (1) to (14).

(16)

A magnetic memory including: the magnetoresistive element according to any one of (1) to (14).

### REFERENCE SIGNS LIST

10 BASE LAYER
11 FIRST MAGNETIC LAYER
12 FIRST NONMAGNETIC LAYER
13 SECOND MAGNETIC LAYER
14 SECOND NONMAGNETIC LAYER
15 THIRD NONMAGNETIC LAYER
16 THIRD MAGNETIC LAYER
41 FIRST WIRING LINE
42 SECOND WIRING LINE
51 INSULATING MATERIAL LAYER
60 SILICON SEMICONDUCTOR SUBSTRATE
61 GATE ELECTRODE
62 GATE OXIDE FILM
63 CHANNEL FORMATION REGION
64A, 64B SOURCE/DRAIN REGION
TR SELECTION TRANSISTOR
65, 66 CONNECTION HOLE
67 FIRST INTERLAYER INSULATING LAYER
68 SECOND INTERLAYER INSULATING LAYER
100 MAGNETORESISTIVE ELEMENT

1. A magnetoresistive element comprising:
a first magnetic layer stacked on a base layer; a second magnetic layer; and a first nonmagnetic layer arranged between the first magnetic layer and the second magnetic layer, wherein
the first nonmagnetic layer includes
an insulating material including fluorine.

2. The magnetoresistive element according to claim 1, wherein
the first nonmagnetic layer includes
the insulating material including fluorine, oxygen, or nitrogen.

3. The magnetoresistive element according to claim 1, further comprising
a second nonmagnetic layer between the first nonmagnetic layer and the second magnetic layer, wherein
the second nonmagnetic layer includes
a nonmagnetic layer having a stacked structure in which a fluoride insulator, an oxide insulator, or a nitride insulator is used.

4. The magnetoresistive element according to claim 1, wherein
a perpendicular magnetization film is used for both the first magnetic layer and the second magnetic layer, or any one of the first magnetic layer or the second magnetic layer.

5. The magnetoresistive element according to claim 1, wherein
the first nonmagnetic layer includes
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, or TiO₂F.

6. The magnetoresistive element according to claim 3, wherein
the first nonmagnetic layer and the second nonmagnetic layer include
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MoF₃, NdF₃, TaF₃, NbOF₂, TaO₂F, or TiO₂F, an oxide including at least any one of Mg, Al, Ti, Si, Zn, Zr, Hf, Ta, Bi, Cr, Ga, La, Gd, Sr, or Ba, or a nitride including at least any one of Mg, Al, Ti, Si, Zn, Zr, Hf, Ta, Bi, Cr, Ga, La, Gd, Sr, or Ba.

7. The magnetoresistive element according to claim 1, wherein
the first nonmagnetic layer includes
LiF.

8. The magnetoresistive element according to claim 3, wherein
as a stacked structure of the first nonmagnetic layer and the second nonmagnetic layer,
a stacked structure of fluoride and MgO is used.

9. The magnetoresistive element according to claim 1, further comprising
a third nonmagnetic layer on the second magnetic layer, wherein
the third nonmagnetic layer includes
at least any one kind of fluoride of LiF, NaF, AgF, CsF, KF, RbF, CuF₂, CoF₂, MgF₂, MnF₂, NiF₂, PdF₂, ZnF₂, CaF₂, SrF₂, PbF₂, BaF₂, CdF₂, EuF₂, AlF₃, BiF₃, InF₃, CrF₃, FeF₃, GaF₃, RhF₃, SbF₃, AuF₃, HfF₄, SnF₄, ZrF₄, TiF₄, NbF₅, TaF₅, WF₆, CeOF, HOOF, LaOF, NdOF, PrOF, FeF₃, MOF₃, NdF₃, TaF₃, NbOF₂, TaO₂F, or TiO₂F, an oxide including at least any one of Mg, Al, Ti, Si, Zn, Zr, Hf, Ta, Bi, Cr, Ga, La, Gd, Sr, or Ba, or a nitride including at least any one of Mg, Al, Ti, Si, Zn, Zr, Hf, Ta, Bi, Cr, Ga, La, Gd, Sr, or Ba.

10. The magnetoresistive element according to claim 9, further comprising
a third magnetic layer on the third nonmagnetic layer.

11. The magnetoresistive element according to claim 10, wherein
as the first magnetic layer, the second magnetic layer, and the third magnetic layer,
a magnetic thin film having a bcc (001) crystal structure is used.

12. The magnetoresistive element according to claim 10, wherein
as the first magnetic layer, the second magnetic layer, and the third magnetic layer,
a magnetic thin film having an amorphous structure is used.

13. The magnetoresistive element according to claim 1, wherein
as the first magnetic layer,
a magnetic thin film having a bct (001) crystal structure is used.

14. The magnetoresistive element according to claim 13, wherein
as the base layer,
Ir is used.

15. A magnetic sensor comprising: the magnetoresistive element according to claim 1.

16. A magnetic memory comprising: the magnetoresistive element according to claim 1.
